(19) United States
(12) Patent Application Publication
(10) Pub. No.: US 2025/0336641 A1
(43) Pub. Date: Oct. 30, 2025

(54) Transmission Charged Particle Beam Device and Ronchigram Imaging Method

(71) Applicant: Hitachi High-Tech Corporation, Minato-ku, Tokyo (JP)

(72) Inventors: Kazuki ISHIZAWA, Tokyo (JP); Yudai KUBO, Tokyo (JP); Michiko SUZUKI, Tokyo (JP)

(21) Appl. No.: 18/866,838

(22) PCT Filed: Jun. 16, 2022
(86) PCT No.: PCT/JP2022/024228

§ 371 Date: Nov. 18, 2024

(51) Int. Cl. H01J 37/28; H01J 37/20; H01J 37/22

(52) U.S. Cl. CPC H01J 37/28; H01J 37/20; H01J 37/222

(57) ABSTRACT

Displacement in a positional relationship between a focal point and a sample is performed with high accuracy and high speed. A transmission charged particle beam device is an device that acquires a Ronchigram of a sample 59 and performs aberration correction. The device includes a piezoelectric element 65 that displaces the sample by expanding and contracting, a position detection element 72 that detects a position of the sample 59, a control unit 35 that controls an amount of expansion or contraction of the piezoelectric element 65 on the basis of the position of the sample 59 detected by the position detection element 72 such that the sample 59 is displaced and the sample 59 is stopped, and an imaging unit 20 that images one or a plurality of single Ronchigrams without changing a focal position of the beam with which the sample 59 is irradiated in a state where the sample 59 is stopped.

### TECHNICAL FIELD

The present disclosure relates to a transmission charged particle beam device and a Ronchigram imaging method.

### BACKGROUND ART

Recently, atomic column observation in the reduction in size of semiconductor devices and material development has been more important. Thus, there have been demands for higher resolution and higher contrast in transmission electron microscopes (TEMs) and scanning transmission electron microscopes (STEMs).

In STEMs, in order to achieve high resolution, it is necessary to reduce a diameter of an electron beam probe that scans a sample. However, the diameter of the probe is restricted by aberrations of an electron optical system. Further, in order to increase a current of the probe for high resolution, it is necessary to increase an angle (opening angle a) formed between an optical axis and an electron beam at the maximum angle when being converged by the probe. The increase in angle further increases aberrations and is one factor of deterioration in resolution.

Therefore, recently, STEMs and TEMs equipped with aberration correctors have been practically used. Using the aberration corrector, positive third-order spherical aberration generated in the electron optical system can be canceled by negative third-order spherical aberration generated by a multipole lens. Thereby, it is possible to perform high-resolution and high-contrast imaging.

In a case where the opening angle a is further increased after the third-order spherical aberration is canceled, the effect of fifth-order spherical aberration deteriorates the resolution. However, it has been known that the fifth-order spherical aberration can be corrected by associating the aberration corrector with the objective lens under appropriate transfer conditions.

In a general structure of the aberration corrector, the aberration corrector includes a plurality of multipole lenses, a plurality of transfer lenses, and a plurality of adjustment lenses.

As a basic aberration correction method, there is PTL 1. PTL 1 describes that “between the first sextupole and the second sextupole, two circular lenses having the same focal length are disposed to be distanced by twice the focal length from each other and to be distanced by the focal length of the circular lens from the plane passing through the centers of the sextupoles adjacent to the respective circular lenses”.

Further, as a configuration of an aberration corrector and a method of correcting the first-to-third-order parasitic aberrations, for example, there is PTL 2. PTL 2 discloses a technique for independently correcting the two-fold symmetric third-order star distortion (S3) and the four-fold symmetric third-order astigmatism (A3) which secondarily occurs by providing a spherical aberration corrector.

Further, as a pre-stage of correcting the aberrations described in PTL 1 and PTL 2, there is a pre-process of correcting first-order two-fold symmetric astigmatism (A1), second-order one-fold symmetric coma aberration (B2), and second-order three-fold symmetric astigmatism (A2). In addition, as a post-process, there is also a process of performing third-order spherical aberration (C3) and fifth-order spherical aberration (C5).

In a case of correcting each aberration, the aberrations are reduced by adjusting the control signals given to the multipole lens, deflection lens, and transfer lens. In such a case, as one of the means for checking the aberration, the Ronchigram method may be used.

The Ronchigram method is a method of irradiating a sample with a converged electron beam and checking an image (Ronchigram) in which the angular distribution of aberrations caused by the electron beam that has passed through the sample is reflected.

In the basic aberration correction using a Ronchigram, each aberration is corrected, an objective lens focal point is changed from the back focal point to the front focal point by changing the objective lens current, and the aberration correction is performed again in a case where the aberration is determined from a changed state and the aberration remains. Then, the above-mentioned correction is repeated until it is determined that each aberration is eliminated.

According to the aberration correction using a Ronchigram, each aberration can be corrected while being visually checked in sequence. On the other hand, it is necessary to perform a flow of the aberration correction in accordance with the number of aberrations to be corrected. Thus, the number of times the flow is performed becomes very large, and it takes a long time to correct all the aberrations.

PTL 3 discloses, as a method of aberration measurement, a method of measuring aberrations using a Ronchigram (hereinafter referred to as a focal point variation Ronchigram) that minutely changes a positional relationship between a focal point and a sample while imaging one Ronchigram.

By using this method, local aberration information can be extracted from one focal point variation Ronchigram. Therefore, information about the aberration, which is visually captured from the Ronchigram, can be turned into numerical information. Thereby, it is possible to provide simpler aberration correction to a user who has difficulty capturing aberration information from an aberration pattern. In addition, it is possible to easily make an automated flow for aberration correction using a computer by capturing the aberration information as numerical information.

Further, in Embodiment 2 of PTL 3, the minute displacement of the focal point is not caused by excitation of an objective lens, but a method of displacing the sample height is used. In particular, as a means for displacing the sample height, an example in which a piezoelectric element is used is disclosed.

The response of the piezoelectric element to an applied signal is faster than that of an actuator using a motor. Thus, it has a high affinity as a substitute for an objective lens as a means for moving the plurality of periodic focal points. Further, an alternate current operation is required to cause the focal point variation. This operation acts to suppress the displacement creep of the piezoelectric element. As a result, it is also possible to increase accuracy in displacement performed by the piezoelectric element.

### CITATION LIST

### Patent Literature

PTL 1: JP2002-510431A

PTL 2: JP2012-234755A

PTL 3: JP2015-056376A

### SUMMARY OF INVENTION

### Technical Problem

In Embodiments 1 and 3 of PTL 3, displacement in positional relationship between the focal point and the sample is performed using an electromagnetic means in the process of imaging the focal point variation Ronchigram. Such a method does not cause a problem in that the displacement is an operation using an alternate current in a case of imaging the focal point variation Ronchigram. However, in a case of imaging a Ronchigram which does not cause variation in the positional relationship between the focal point and the sample during imaging of one Ronchigram (hereinafter referred to as a single Ronchigram), the accuracy in the positional relationship between the focal point and the sample does not increase due to an effect of magnetic hysteresis. Further, drift due to the temperature change in a lens coil may be caused by change in the lens current. In addition, since the change in magnetic flux of the lens coil has a time constant, it takes time to image a plurality of Ronchigrams.

In a case of changing the positional relationship between the focal point and the sample using the lens coil, particularly in a case of moving across the front focal point and the back focal point, the time required to maintain a substantially right focal point in the sample becomes long due to the time constant of the magnetic flux change of the lens coil. This damages an amorphous thin film, which is the sample necessary for acquiring the Ronchigram, and deteriorates the quality of the Ronchigram.

Embodiment 3 of PTL 3 discloses a method of performing displacement in the positional relationship between the focal point and the sample by using the piezoelectric element in the process of imaging the focal point variation Ronchigram. Such a method does not cause a problem in that the displacement is driven by an alternate current signal in a case of imaging the focal point variation Ronchigram. However, in a case of imaging a single Ronchigram or a focal point variation Ronchigram at a plurality of positions, the accuracy in the positional relationship between the focal point and the sample does not increase due to the effect of the displacement hysteresis of the piezoelectric element. Further, the piezoelectric element has a large displacement creep, and in an operation in which movement and stopping are repeated, it is necessary for the imaging of a Ronchigram to wait until the displacement creep stops. Therefore, it takes time to image a plurality of Ronchigrams.

Embodiments 1 to 3 of PTL 3 describe using a plurality of focal point variation Ronchigrams in order to increase the accuracy in aberration measurement. As described in PTL 3, this leads to an increase in number of measurements, and a single focal point variation Ronchigram requires focal point variation in a plurality of periods. Therefore, the time required for aberration measurement greatly increases.

The above description can be summarized as follows.

In the process of imaging a plurality of single Ronchigrams, in a case where displacement in positional relationship between the focal point and the sample is performed by the electromagnetic means, the following problems arise.

As the first problem, the accuracy of the displacement does not increase due to the effect of magnetic hysteresis.

As the second problem, an amount of heat generated changes with the current change of the lens coil used in focal point variation, and temperature drift of the field of view and the focal point is caused by thermal expansion and contraction of the electron microscope components. As the third problem, it takes time to image a plurality of Ronchigrams since the magnetic flux change of the lens coil has a time constant.

Further, in the process of imaging a plurality of single Ronchigrams, in a case where displacement in positional relationship between the focal point and the sample is performed using a piezoelectric element, the following problems arise.

As the fourth problem, the displacement accuracy does not increase due to the effect of displacement hysteresis of the piezoelectric element.

As the fifth problem, it takes time to image a plurality of Ronchigrams due to the effect of displacement creep of the piezoelectric element.

Therefore, the present disclosure provides a transmission charged particle beam device and a Ronchigram imaging method capable of solving the above-mentioned five problems.

### Solution to Problem

In order to solve the above-mentioned problems, the transmission charged particle beam device disclosed herein is a transmission charged particle beam device that acquires a Ronchigram of a sample and performs aberration correction. The device includes: a piezoelectric element that displaces the sample by expanding and contracting; a position detection element that detects a position of the sample; a control unit that controls an amount of expansion or contraction of the piezoelectric element on the basis of the position of the sample detected by the position detection element such that the sample is displaced and the sample is stopped; and an imaging unit that images one or more single Ronchigrams without changing a focal position of a beam with which the sample is irradiated in a state where the sample is stopped.

### Advantageous Effects of Invention

According to the present disclosure, displacement in positional relationship between the focal point and the sample can be performed with high accuracy and high speed.

Problems, configurations, and effects other than those described above will be clarified by the following description of the embodiments.

### BRIEF DESCRIPTION OF DRAWINGS

FIG. 1 is a schematic diagram of a transmission charged particle beam device according to Embodiments 1 to 5.

FIG. 2 is a plan view illustrating details of a stage in FIG. 1.

FIG. 3 is a side view illustrating the details of the stage in FIG. 1.

FIG. 4 is a block diagram illustrating details of a piezoelectric element control unit in FIG. 2 or FIG. 3.

FIG. 5 is a block diagram illustrating a modification example of the piezoelectric element control unit in FIG. 4.

FIG. 6 is a diagram illustrating a positional relationship between a focal point and a sample, according to Embodiment 1.

FIG. 7 is a graph illustrating a method of controlling a Z piezoelectric element having a Z position detection element in a case of acquiring a plurality of single Ronchigrams, according to Embodiment 1.

FIG. 8 is an example of imaging the plurality of single Ronchigrams, according to Embodiment 1.

FIG. 9 is a diagram illustrating a thickness of a sample and a positional relationship between a focal point and a sample, according to Embodiment 2.

FIG. 10 is a graph illustrating a method of controlling a Z piezoelectric element having a Z position detection element in a case of acquiring a plurality of single Ronchigrams, according to Embodiment 2.

FIG. 11 is a graph illustrating a method of controlling each piezoelectric element having a position detection element in a case of acquiring a plurality of single Ronchigrams, according to Embodiment 3.

FIG. 12 is a diagram illustrating a relationship between an imaging position and a retraction position of a single Ronchigram, according to Embodiment 3.

FIG. 13 is a graph illustrating a method of controlling each piezoelectric element having a position detection element in a case of acquiring a plurality of single Ronchigrams, according to Embodiment 4.

FIG. 14 is a diagram illustrating an imaging position of the plurality of single Ronchigrams, according to Embodiment 4.

FIG. 15 is a diagram illustrating a positional relationship between a tilted focal point and a sample according to Embodiment 5.

FIG. 16 is a plan view illustrating details of a modified stage according to Embodiments 1 to 5.

FIG. 17 is a side view illustrating details of a stage relating to a modified stage of FIG. 16.

### DESCRIPTION OF EMBODIMENTS

Hereinafter, embodiments will be described in detail with reference to the drawings. In all drawings used to illustrate the embodiments, members having the same function are represented by the same reference numerals and signs. In the following embodiments, the description about the same or similar parts will not be repeated in principle unless particularly necessary.

Further, an X direction, a Y direction, and a Z direction described in the present application intersect with each other and are orthogonal to each other. In the present application, the Z direction is described as the vertical direction, height direction, or thickness direction of a certain structure. Further, expressions such as the “plan view” or “planar view” used in the present application mean that a plane formed by the X direction and the Y direction is viewed from the Z direction. Expressions such as the “cross-sectional view” or “sectional view” refer to a plane formed including the Z direction and the X direction, or the Y direction, or quantity components of X-Y.

For the purpose of description, a transmission electron microscope or a scanning transmission electron microscope with a stage that enters from the side will be described as an example of a charged particle beam device. However, the charged particle beam device according to the present invention is not limited to the transmission electron microscope or the scanning transmission electron microscope, and is also not limited to those with a stage that enters from the side.

### Embodiment 1

### <Structure of Transmission Charged Particle Beam Device 1>

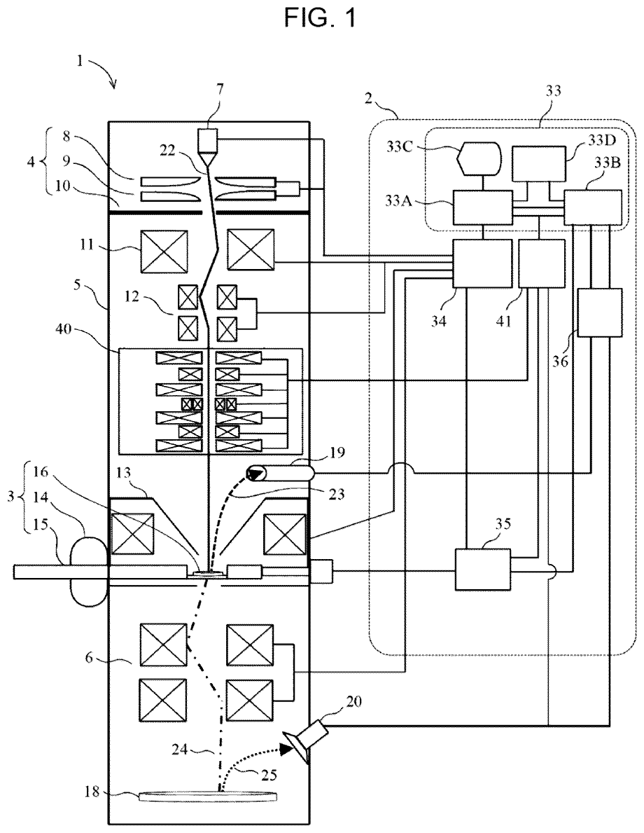

Hereinafter, a transmission charged particle beam device according to Embodiment 1 will be described with reference to FIG. 1. Embodiment 1 shows a side-entry type transmission electron microscope (TEM) or a scanning transmission electron microscope (STEM) as an example of the transmission charged particle beam device 1. The transmission charged particle beam device 1 according to Embodiment 1 acquires a Ronchigram of a sample and performs automatic or manual aberration correction.

The transmission charged particle beam device 1 is configured to include an electron gun 4, an electron optical system 5, an imaging system 6, and a stage 3 that displaces the sample, in an integrated manner. In a lens barrel of the transmission charged particle beam device 1, a vacuum is maintained using a vacuum exhaust means not illustrated in the drawing.

Primary electrons 22 are emitted from an electron source 7. The primary electrons 22 are collected and accelerated using a suppression electrode 8, an extraction electrode 9, and an anode 10 in the electron gun 4. Then, the primary electrons 22 are magnified or reduced and deflected by a focusing lens 11 and a deflection lens 12 in the electron optical system 5. Thereafter, an aberration corrector 40 performs magnification, reduction, shift, tilt, and the like on the primary electrons 22 and corrects aberrations. Subsequently, an objective lens 13 adjusts a focal point of the primary electrons 22. Then, the sample placed on a sample holder 16 at a tip of a stage rod 15 is irradiated with the primary electrons 22.

Signal electrons 23 are generated, from the sample irradiated with the primary electrons 22, by reflection and emission of secondary electrons. A detector 19 detects the signal electrons 23. The signal, which is output from the detector 19, is processed by a signal processing unit 36, and then processed (created as an image) by an image processing unit 33B and a CPU 33A in a computer 33, and displayed on a display device 33C.

Further, the imaging system 6 reduces and magnifies electrons passing through the sample (transmitted electrons 24) among the electrons with which the sample is irradiated, and irradiates a fluorescent screen 18 with the electrons. When being irradiated with the transmitted electrons 24, the fluorescent screen 18 generates fluorescence 25. A camera 20 (imaging unit) detects the generated fluorescence 25. The signal, which is output from the camera 20, is processed by the signal processing unit 36, and then processed (created as an image) by the image processing unit 33B and the CPU 33A in the computer 33, and displayed on the display device 33C.

The transmission charged particle beam device 1 may also include a detector such as a charged particle beam detector, an optical detector, a camera, an X-ray detector, or the like which is not illustrated in the drawing, and may also include an aperture mechanism and the like relating to such a detector.

The stage 3 includes a stage driving mechanism 14, the stage rod 15, and the sample holder 16. The sample holder 16 is connected to the tip of the stage rod 15. The sample is placed on the sample holder 16. A position of the field of view is changed by driving the stage 3. In a case of adjusting the position of the field of view, the stage driving mechanism 14 operates in response to a command issued from a stage control unit 35 to realize movements such as pushing, pulling, rotating, and feeding the stage rod 15. The movements may be realized through atmospheric pressure or spring force, or by offsetting atmospheric pressure or spring force applied in advance. Although not illustrated here, the stage driving mechanism 14 includes a piezoelectric element and a position detection element.

A control device 2 (control unit) includes the computer 33, a main control unit 34, a stage control unit 35, the signal processing unit 36, and an aberration corrector control unit 41. The control device 2 controls each component of the transmission charged particle beam device 1.

The computer 33 can be configured using a computer having a known configuration. For example, the computer 33 includes a calculation means for performing calculations, a storage means for storing information, and an input/output means for inputting and outputting information. The storage means includes, for example, a non-transitory storage medium. The storage means is able to store a program. By the calculation means executing the program, the computer 33 realizes an operation described in the present specification. Accordingly, the transmission charged particle beam device 1 realizes the operation described in the present specification. Consequently, the program causes the transmission charged particle beam device 1 to execute the method described in the present specification.

In the present embodiment, the calculation means includes the CPU 33A and the image processing unit 33B, the input/output means includes the display device 33C, and the storage means includes a memory 33D as the storage medium. The computer 33 is able to perform calculation relating to a signal and transmission and reception of information (a command and the like) to and from each device. The computer 33 also serves as an interface with a person and another electronic device.

The main control unit 34 includes an amplifier, an analog-to-digital converter, a digital-to-analog converter, various logics, and the like, and provides signals, powers, and voltages to the electron gun 4, the electron optical system 5, the imaging system 6, the camera 20, the stage 3, and the like. The main control unit 34 also receives signals and performs various kinds of processing and control. The main control unit 34 also includes a plurality of memories that store a program for controlling each of the components, and one or a plurality of CPUs and one or a plurality of FPGAs that process the program. The CPU and FPGA communicate with the computer 33 and control each of the CPU and FPGA on the basis of commands from the computer 33 or results of calculations in the CPU.

The stage control unit 35 receives instructions relating to the movement, rotation, tilt, and the like of the stage 3 from the computer 33 or the main control unit 34, and controls the stage driving mechanism 14. Although not illustrated here, the stage control unit 35 includes a piezoelectric driver and a position detection element control unit.

The aberration corrector control unit 41 controls the multiple magnetic poles and electrodes included in the aberration corrector 40, and performs an aberration correction operation. During the aberration recognition operation, the signal processing unit 36 or the image processing unit 33B processes the Ronchigram imaged by the camera 20, and a user observes a displayed image and recognizes the aberrations. Then, the user adjusts the aberration corrector control unit 41, and performs the aberration correction operation. Alternatively, the image processing unit 33B performs aberration calculation, and the computer 33 automatically sends a command to the aberration corrector control unit 41 on the basis of the result, and performs the aberration correction operation.

### <Structure of Stage 3>

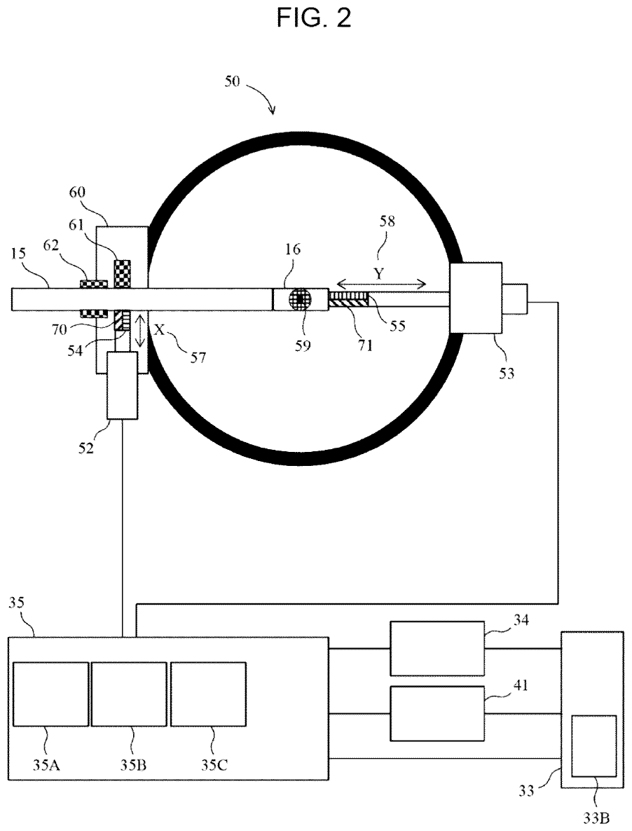

FIG. 2 is a plan view illustrating details of the stage 3 in FIG. 1. The details of the stage operation in the X and Y directions will be described using FIG. 2.

A lens barrel 50 is provided with an X actuator 52, a Y actuator 53, and a stage rod insertion mechanism 60. The stage rod 15 is inserted into the lens barrel 50 through the stage rod insertion mechanism 60. An X piezoelectric element 54 and an X position detection element 70 are mounted on the tip of the X actuator 52. A Y piezoelectric element 55 and a Y position detection element 71 are mounted on the tip of the Y actuator 53. The X piezoelectric element 54, the Y piezoelectric element 55, and a Z piezoelectric element 65 to be described later expand and contract by an amount of expansion or contraction corresponding to the applied voltage, displacing the sample. Further, the X position detection element 70, the Y position detection element 71, and the Z position detection element 72 respectively detect absolute positions of the sample displaced by the X piezoelectric element 54, the Y piezoelectric element 55, and the Z piezoelectric element 65.

The X actuator 52 and the X piezoelectric element 54 are pressurized by a X support 61, supporting the stage rod 15. The Y actuator 53 and the Y piezoelectric element 55 are pressurized by a Y support 62, supporting the stage rod 15.

The stage 3 moves the stage rod 15 and the sample holder 16 in an X direction 57 by using the X actuator 52 and the X piezoelectric element 54. Further, the stage 3 moves the stage rod 15 and the sample holder 16 in a Y direction 58 by using the Y actuator 53 and the Y piezoelectric element 55.

The sample holder 16 is connected to the tip of the stage rod 15. A sample 59 is placed on the sample holder 16. The sample 59 is a target to be observed. The sample 59 includes an amorphous thin film necessary for acquiring the Ronchigram.

The X actuator 52 and the Y actuator 53 perform relatively rough displacement (hereinafter referred to as coarse movement) among displacements of the sample performed by the stage 3. On the other hand, the X piezoelectric element 54 and the Y piezoelectric element 55 perform relatively small displacement (hereinafter referred to as fine movement) among displacements of the sample performed by the stage 3. In the present embodiment, the displacements of the sample, which are performed by the X piezoelectric element 54 and the Y piezoelectric element 55, are performed while the amounts of expansion or contraction due to the piezoelectric effects of the X piezoelectric element 54 and the Y piezoelectric element 55 are respectively fed back by the X position detection element 70 and the Y position detection element 71. The coarse movement and the fine movement are realized as a movement such as pushing, pulling, turning, or feeding the stage rod 15 and the sample holder 16. The movements may be realized through atmospheric pressure or spring force, or may be realized by offsetting the atmospheric pressure or spring force applied in advance, or may be realized through a lever not illustrated in the drawing.

The stage control unit 35 controls the X actuator 52, the Y actuator 53, the X piezoelectric element 54, and the Y piezoelectric element 55. The stage control unit 35 includes a stage operation calculation unit 35A, a motor driver 35B, and a piezoelectric element control unit 35C.

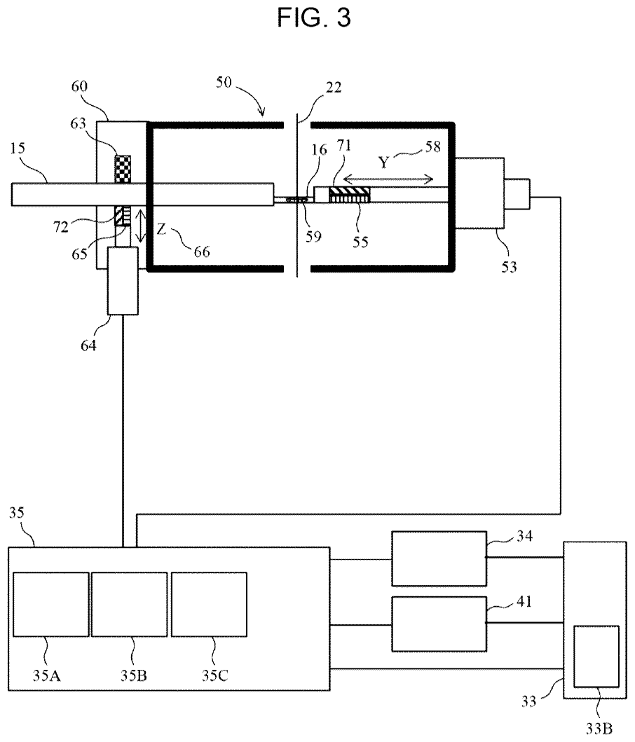

FIG. 3 is a side view illustrating the details of the stage 3 in FIG. 1. The details of the stage operation in the Z direction will be described using FIG. 3. It should be noted that the objective lens 13 is not illustrated to avoid complexity.

FIG. 3 illustrates a Z actuator 64 for moving the stage 3 in a Z direction 66 parallel to a direction of irradiation of the primary electrons 22, the Z piezoelectric element 65, and a Z position detection element 72. The stage 3 moves the stage rod 15 and the sample holder 16 in the Z direction 66 by using the Z actuator 64 and the Z piezoelectric element 65. The Z actuator 64 performs coarse movement of the sample, similar to the X actuator 52 and the Y actuator 53. The Z piezoelectric element 65 performs fine movement of the sample, similarly to the X piezoelectric element 54 and the Y piezoelectric element 55. Further, the Z actuator 64 and the Z piezoelectric element 65 are pressurized by a Z support 63, supporting the stage rod 15.

The Z piezoelectric element 65, of which an amount of displacement is controlled by the Z position detection element 72 and the piezoelectric element control unit 35C, changes a distance between the focal point and the sample in a case of imaging a plurality of single Ronchigrams during aberration correction.

It is assumed that examples of the X position detection element 70, the Y position detection element 71, and the Z position detection element 72 include a distance meter using capacitance, a distance meter using a laser, a linear encoder, a strain gauge, and the like. Examples of each of the X support 61, the Y support 62, and the Z support 63 include various elements such as a spring, a counter-action spring, a leaf spring mechanism, hard rubber, and atmospheric pressure.

The transmission charged particle beam device 1 may further include a tilt axis and an azimuth axis (axis for tilting the sample with respect to the beam) not illustrated in the drawing, and may include a rotation axis for rotating the sample itself.

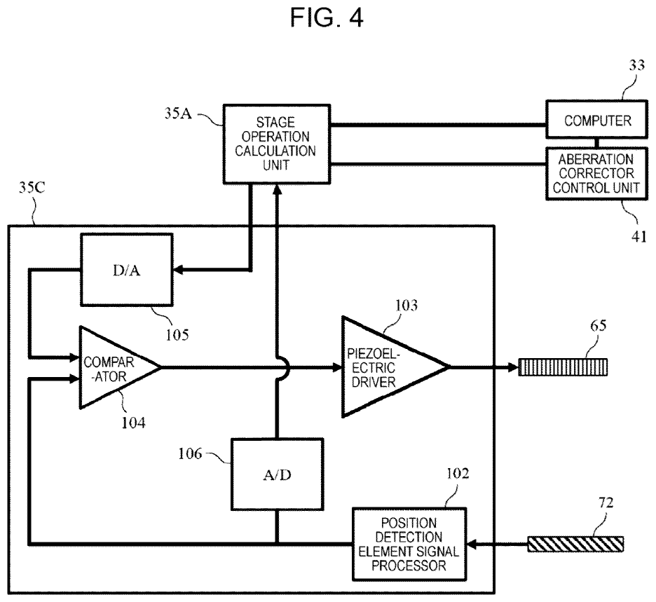

FIG. 4 is a block diagram illustrating the details of the piezoelectric element control unit 35C in FIG. 2 or FIG. 3. The piezoelectric element control unit 35C is provided for each of the X piezoelectric element 54, the Y piezoelectric element 55, and the Z piezoelectric element 65. In the following description, the piezoelectric element control unit 35C which controls the amount of displacement of the Z piezoelectric element 65 will be described. It should be noted that the piezoelectric element control unit, which controls the amount of displacement of the X piezoelectric element 54, and the piezoelectric element control unit, which controls the amount of displacement of the Y piezoelectric element 55, are similar to the piezoelectric element control unit 35C, and therefore description thereof will not be repeated.

The computer 33 or the aberration corrector control unit 41 issues a command of the amount of displacement performed by the Z piezoelectric element 65 to the stage operation calculation unit 35A. The stage operation calculation unit 35A, which receives the command, issues a command of the amount of displacement to a digital-to-analog converter 105 in the piezoelectric element control unit 35C, and inputs an analog signal to a comparator 104. The comparator 104 outputs an analog signal to a piezoelectric driver 103. Then, the piezoelectric driver 103 applies a voltage to the Z piezoelectric element 65 in accordance with the output from the comparator 104. The Z piezoelectric element 65, to which the voltage is applied, expands and contracts by an amount of expansion or contraction corresponding to the applied voltage. The Z position detection element 72 detects the amount of expansion or contraction, and a signal such as a voltage, charge, current, pulse, or frequency corresponding to the amount of expansion or contraction is output. The signal, which is output from the Z position detection element 72, is converted and amplified into a form of signal (for example, voltage) easily processed by a position detection element signal processor 102, and is input to the comparator 104. The comparator 104 compares the signal of the digital-to-analog converter 105 with the signal which is output from the position detection element signal processor 102. Then, in a case where there is a difference between the signal of the position detection element signal processor 102 and the voltage (command value) of the digital-to-analog converter 105, the signal, which is output from the comparator 104, is changed such that the difference is eliminated.

Simply expressed, the piezoelectric element control unit 35C is analog feedback of the amount of displacement of the Z piezoelectric element 65 using the Z position detection element 72.

Here, an analog-to-digital converter 106 is responsible for constantly inputting the output of the Z position detection element 72 to the stage operation calculation unit 35A. The stage operation calculation unit 35A is able to check whether the amount of displacement of the Z piezoelectric element 65 reaches the target value and whether the Z piezoelectric element 65 is stationary, on the basis of the output of the analog-to-digital converter 106.

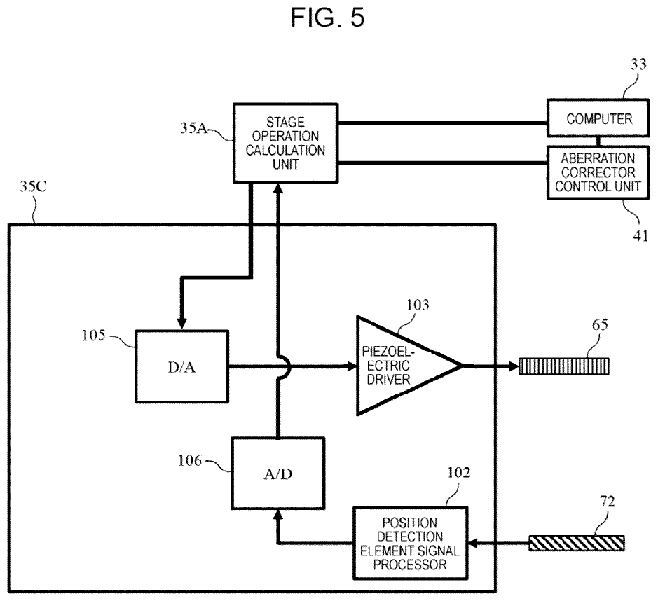

FIG. 5 is a block diagram illustrating a modification example of the piezoelectric element control unit in FIG. 4. In the configuration of FIG. 5, the signal, which is output by the analog-to-digital converter 106, is compared with a target amount of displacement in the stage operation calculation unit 35A, and calculated without using an analog comparator. Simply expressed, the configuration is digital feedback of an amount of displacement.

The Z position detection element 72 detects the amount of expansion or contraction of the Z piezoelectric element 65. However, the Z position detection element 72 is not limited to an element that detects the amount of expansion or contraction of the Z piezoelectric element 65 as long as the element is able to detect an absolute amount of displacement of the sample performed by the Z piezoelectric element 65.

### <Method of Controlling Z Piezoelectric Element 65 Having Z Position Detection Element 72 (Embodiment 1)>

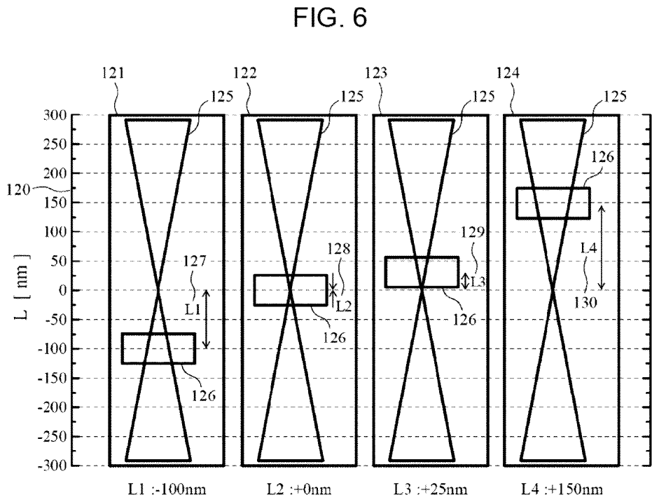

FIG. 6 is a diagram illustrating a positional relationship between the focal point and the sample, according to Embodiment 1. In an axis 120 indicating the distance L[nm], the unit is [nm] and indicates a distance between the focal point of the beam and the sample.

A schematic diagram 121 of the positional relationship between the focal point and the sample includes a schematic beam trajectory diagram 125 and a sample 126, and a focal position of the schematic beam trajectory diagram 125 is fixed at a position of 0 nm on the axis 120. At this time, a distance L1 (127) between the focal point and the sample is −100 nm, which indicates the back focal point.

Further, in a schematic diagram 122 of the positional relationship between the focal point and the sample, a distance L2 (128) between the focal point and the sample is 0 nm, which indicates the right focal point. Furthermore, in a schematic diagram 123 of the positional relationship between the focal point and the sample, a distance L3 (129) between the focal point and the sample is +25 nm, which indicates the front focal point. Moreover, in a schematic diagram 124 of the positional relationship between the focal point and the sample, a distance L4 (130) between the focal point and the sample is +150 nm, which indicates the front focal point.

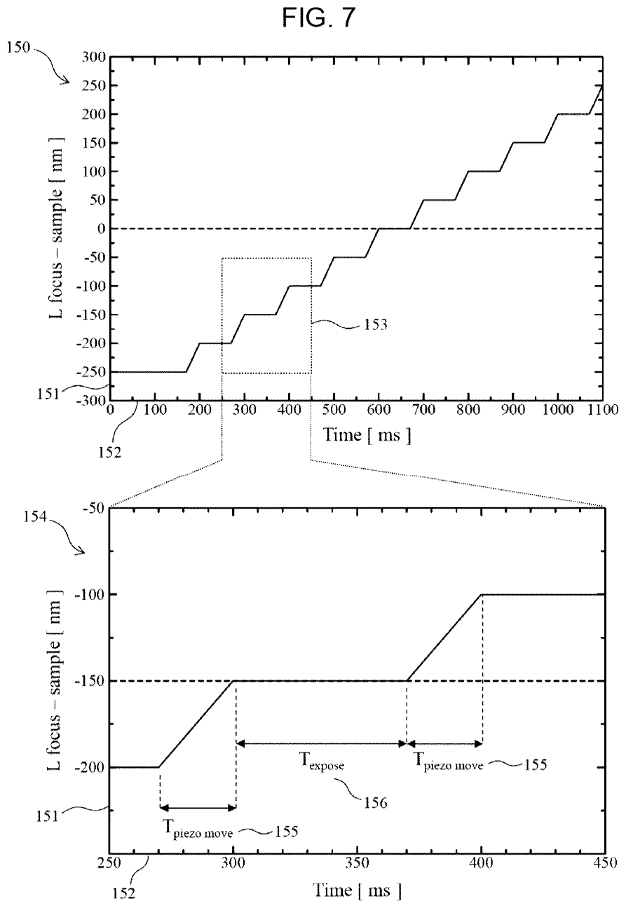

In a case of acquiring a plurality of single Ronchigrams, as illustrated in the schematic diagrams 121 to 124 of the positional relationship between the focal point and the sample, the focal point of the beam is fixed, and the position of the sample 126 is displaced by the Z piezoelectric element 65 having the Z position detection element 72, varying the distance between the focal point and the sample. A specific control example is disclosed in FIG. 7.

FIG. 7 is a graph illustrating a method of controlling the Z piezoelectric element 65 having the Z position detection element 72 in a case of acquiring a plurality of single Ronchigrams, according to Embodiment 1. A vertical axis 151 of a graph 150 is a distance between the focal point and the sample (L focus-sample [nm]), and a horizontal axis 152 is the time (Time [ms]). 0 nm on the vertical axis indicates the right focal point. Further, a positive region of the vertical axis is the front focal point, and a negative region of the vertical axis is the back focal point. A value on the vertical axis (the distance L between the focal point and the sample) is the same as the amount of displacement of the stage 3 performed by the Z piezoelectric element 65 and the Z position detection element 72.

A T_{piezo move} 155 illustrated in a graph 154, which is an enlarged view of an enlarged region 153 in the graph 150, indicates the time from the start of displacement of the Z piezoelectric element 65 to a stationary state. A Tₑₓₚₒₛₑ 156 indicates the exposure time of the camera in a case of imaging the single Ronchigram.

The displacement of the Z piezoelectric element 65 having the Z position detection element 72 is characterized in that the Z piezoelectric element 65 can be stationary immediately after displacement. Thereby, it is possible to image the single Ronchigram immediately after the displacement of Z piezoelectric element 65 is completed.

Using the control method, the position of the focal point and the sample is changed stepwise by repeating the operation of moving the sample to a specified position in the time of the T_{piezo move} 155 and imaging the Ronchigram in the time of the Tₑₓₚₒₛₑ 156, and a plurality of single Ronchigrams are imaged each time the sample stops.

According to the characteristic, the time required for the Z piezoelectric element 65 having the Z position detection element 72 to perform displacement and be stationary is 30 ms, and the exposure time of the camera in a case of imaging the single Ronchigrams is 70 ms. Therefore, it is possible to image ten single Ronchigrams per second.

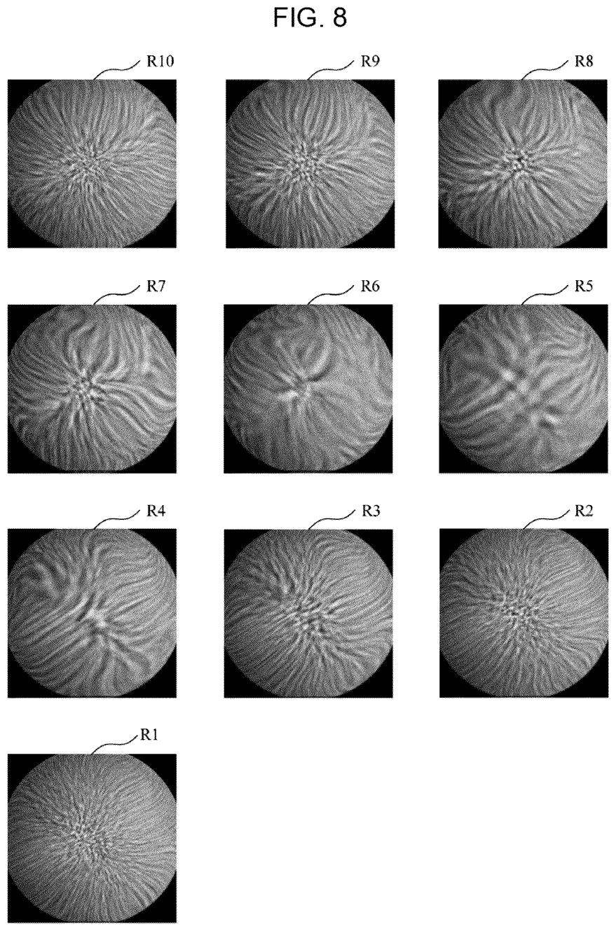

FIG. 8 illustrates an example of imaging a plurality of single Ronchigrams, according to Embodiment 1. R1, R2, R3, and R4 are single Ronchigrams at the back focal point. R5 is a single Ronchigram at the right focal point. R6, R7, R8, R9, and R10 are single Ronchigrams at the front focal point.

It is possible to calculate aberrations with high accuracy by processing all images of R1 to R10 or any single Ronchigram among R1 to R10 through the image processing unit 33B and extracting aberration information at the distance between each focal point and the sample.

### <Effects of Embodiment 1>

According to Embodiment 1, the configuration, in which the plurality of single Ronchigrams are imaged with different distances between the focal point and the sample by using the Z piezoelectric element 65 having the Z position detection element 72, and the method of controlling the Z piezoelectric element 65 having the Z position detection element 72 are capable of obtaining the following effects.

First, the displacement control of the sample can be performed with an order of 0.1 nm, by displacing the distance between the focal point and the sample through the Z piezoelectric element 65 having the Z position detection element 72. With such a configuration, the first problem that “the displacement accuracy cannot be increased due to the effect of magnetic hysteresis” is solved. Thereby, it is possible to increase the accuracy of the displacement and increase the accuracy of the aberration calculation.

At the same time, the fourth problem that “the accuracy of the displacement cannot be increased due to the effect of the displacement hysteresis of the piezoelectric element” is also solved. Thereby, it is possible to increase the accuracy of the displacement and increase the accuracy of the aberration calculation.

Next, in a case of imaging a single Ronchigram, the piezoelectric element is close to direct current driving. Direct-current-driven piezoelectric elements are less likely to generate heat. Therefore, temperature drift is not caused by the displacement in the distance between the focal point and the sample. With such a configuration, the second problem that “the amount of heat generated changes with the change in current of the lens coil used in focal point variation, and temperature drift occurs in the field of view and the focal point due to thermal expansion and contraction of the electron microscope components” is solved. Thereby, drift of the field of view or focal point does not occur during aberration correction. It should be noted that in a case of acquiring a focal point variation Ronchigram, the piezoelectric element is driven with an alternate current. Therefore, heat is generated due to the effect of Tanδ of the piezoelectric element. As a result, it is difficult to solve the problem.

Further, in a case of displacing the distance between the focal point and the sample by using the Z piezoelectric element 65 having the Z position detection element 72, a period from the start of displacement to the end of displacement (stationary state) is about 20 to 40 μs. With such a configuration, the third problem that “it takes time to image the plurality of Ronchigrams since the magnetic flux change of the lens coil has a time constant (about 1 second)” is solved. Thereby, it is possible to shorten the time required to image the plurality of single Ronchigrams.

At the same time, the fifth problem that “it takes time to image the plurality of Ronchigrams due to the effect of displacement creep of the piezoelectric element” is also solved. Thereby, it is possible to shorten the time required to image the plurality of single Ronchigrams.

### Embodiment 2

### <Method of Controlling Z Piezoelectric Element 65 Having Z Position Detection Element 72 (Embodiment 2)>

It is known that an amorphous thin film is damaged in a case where the focal point of the beam stays in the amorphous thin film included in the sample. Therefore, it is necessary to minimize the time during which the focal point of the beam stays in the amorphous thin film. Thus, in Embodiment 2, in a case where the sample is displaced to pass the focal position, the sample is displaced without stopping the sample at least in a range where the focal position enters the sample. Further, in Embodiment 2, in a case where the sample is displaced to pass the focal position, the sample is displaced at a moving speed faster than a moving speed of the sample before or after the focal position of the beam enters the sample, at least in the range where the focal position enters the sample.

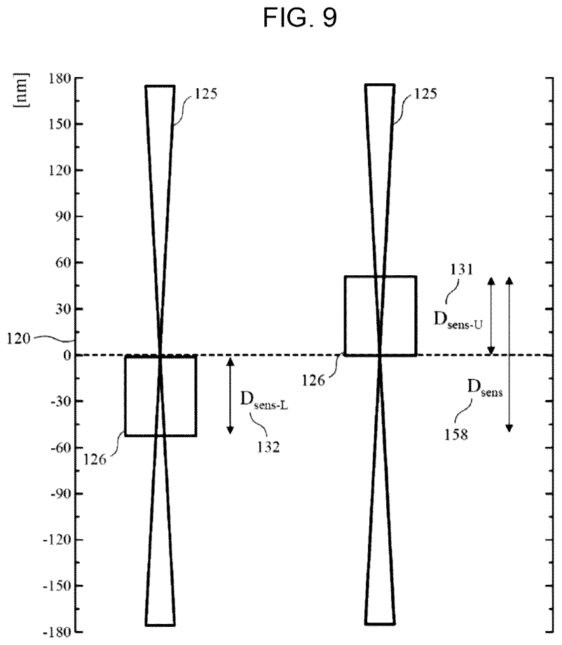

FIG. 9 is a diagram illustrating a relationship between the thickness of the sample and the distance between the focal point and the sample, according to Embodiment 2. A distance between the sample and the focal point of the beam focused in the sample 126 (including the amorphous thin film) is D_{sens-L} 132 on the back focal point side and D_{sens-U} 131 on the front focal point side. Both D_{sens-L} 132 and D_{sens-U} 131 are the same as the thickness of the sample. In the present embodiment, a sum of the two values is set as Dₛₑₙₛ 158, and Dₛₑₙₛ 158 is defined as a region in which the amorphous thin film is likely to be damaged.

In the present embodiment, for simplicity of description, a region, in which the focal point is in the sample, is set as a region in which the amorphous thin film is likely to be damaged. However, even in a case where the focal point is not in the amorphous thin film, the closer the focal point and the amorphous thin film surface are, the more damage the amorphous thin film suffers.

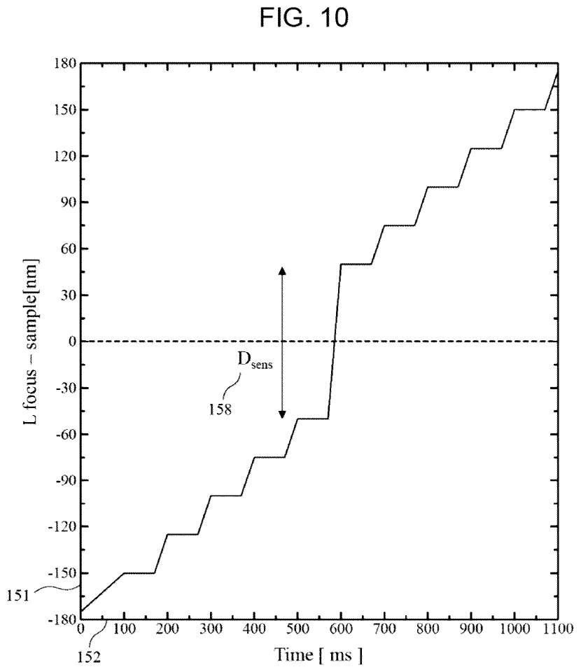

FIG. 10 is a graph illustrating a method of controlling the Z piezoelectric element 65 having the Z position detection element 72 in a case of acquiring a plurality of single Ronchigrams, according to Embodiment 2. The meanings of the vertical axis 151 and the horizontal axis 152 are the same as those in FIG. 7. Thus, the description thereof will not be repeated. As described above, Dₛₑₙₛ 158 indicates the region where the amorphous thin film is likely to be damaged, particularly, in a case of imaging the Ronchigrams, within the distance, which is the vertical axis 151, between the focal point and the sample.

In a case where the horizontal axis 152 in FIG. 10 is between 0 ms and 570 ms (the distance between the focal point and the sample is between −180 nm and −50 nm), displacement and stop of the sample performed by the Z piezoelectric element 65 are repeated at a predetermined time interval, as in FIG. 7, and the single Ronchigram is imaged during the time in which the sample is stopped.

In a case where the Ronchigram is imaged at the distance between the focal point and the sample which is between −50 nm and 50 nm, the distance between the focal point and the sample is in the region of Dₛₑₙₛ 158, damaging the amorphous thin film and reducing the quality of the Ronchigram. Therefore, in a case where the distance between the focal point and the sample is in the region of Dₛₑₙₛ 158, the Z piezoelectric element 65 having the Z position detection element 72 minimizes the time the sample stays in the region of Dₛₑₙₛ 158 by moving the sample as fast as possible. That is, the moving speed in a case of displacing the sample in the region of Dₛₑₙₛ 158 is faster than the moving speed in a case of displacing the sample outside the region of Dₛₑₙₛ 158. Here, deterioration in quality of the Ronchigram indicates deterioration in contrast of the Ronchigram, and indicates that the Ronchigram includes artifact information of the amorphous thin film.

After the sample moves outside the region of Dₛₑₙₛ 158, the Z piezoelectric element 65 having the Z position detection element 72 repeats again displacement and stop of the sample, and images the Ronchigram in a case where the sample stops.

According to the characteristic, in a case where the time required to displace the Z piezoelectric element 65 having the Z position detection element 72 is 30 ms and the exposure time of the camera in a case of imaging the single Ronchigram is 70 ms, it is possible to image ten Ronchigrams per second while reducing damage to the amorphous thin film by minimizing the stay time in the region of Dₛₑₙₛ 158.

In the present embodiment, ten Ronchigrams are acquired. However, the operation of moving at a high speed in the region of Dₛₑₙₛ 158 may be performed simply in a case of moving across the front focal point and the back focal point.

### <Effects of Embodiment 2>

In addition to the first to fifth problems described above, as a sixth problem, there is the following problem. In a case of moving across the front focal point and the back focal point, the time during which the sample position stays in the vicinity of the right focal point increases due to the effect of the time constant of the lens coil. This damages the amorphous thin film and leads to deterioration in quality of the Ronchigram.

In a case of imaging the plurality of single Ronchigrams using the method of controlling the Z piezoelectric element 65 having the Z position detection element 72 described in Embodiment 2, the following effects can be obtained.

In a case of imaging the plurality of single Ronchigrams while avoiding stay in the region of Dₛₑₙₛ 158 for a long time by using the displacement of the Z piezoelectric element 65 having the Z position detection element 72, it is possible to reduce damage to the amorphous thin film during the imaging of the Ronchigrams. Thereby, it is possible to avoid deterioration in quality of the Ronchigrams. With such a configuration, the sixth problem that “in a case of moving across the front focal point and the back focal point, the time during which the sample position stays in the vicinity of the right focal point increases due to the effect of the lens coil time constant, and this damages the amorphous thin film and leads to deterioration in quality of the Ronchigram” is solved. Other effects are the same as the effects in Embodiment 1.

### Embodiment 3

### <Method of Controlling X, Y, and Z Position Detection Elements and X, Y, and Z Piezoelectric Elements in Case of Imaging Ronchigram>

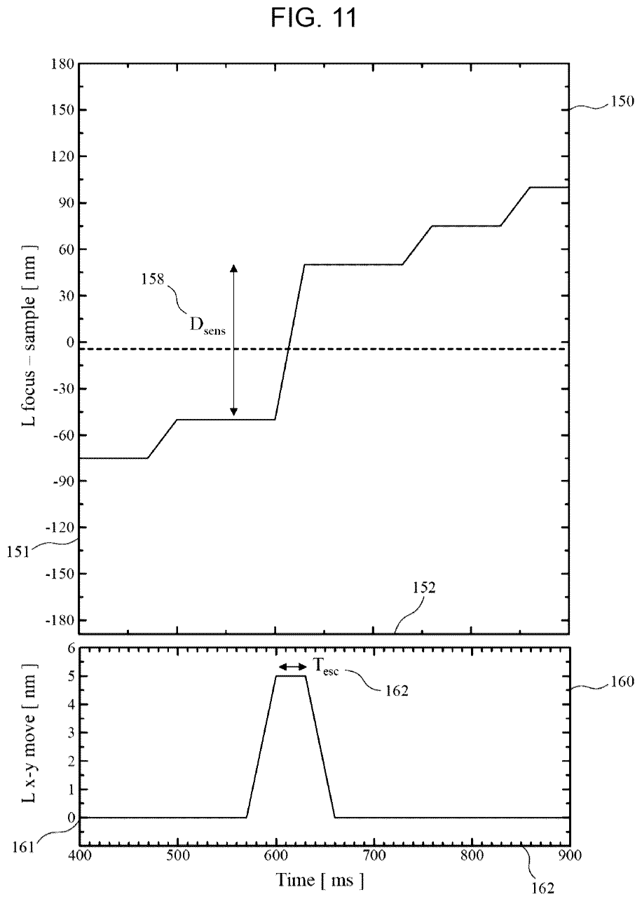

FIG. 11 is a graph illustrating a method of controlling each piezoelectric element having the position detection element in a case of acquiring Ronchigrams, according to Embodiment 3. The graph 150, which illustrates the relationship of the time and the distance between the focal point and the sample, quickly moves through the region of Dₛₑₙₛ 158 in which the amorphous thin film is likely to be damaged, as in FIG. 10. It should be noted that the vertical axis 151 and the horizontal axis 152 in FIG. 11 are the same as in FIG. 10. Thus, the description thereof will not be repeated. However, in FIG. 11, the time scale is in the region from 400 ms to 900 ms. A vertical axis 161 of a graph 160, which illustrates a relationship between the time and a distance of movement in an X-Y plane, is the distance of movement in the X-Y plane, and a horizontal axis 162 is the time, as in FIGS. 7 and 10.

In the present embodiment, in a case where the distance between the focal point and the sample is in the range of Dₛₑₙₛ 158, the X piezoelectric element 54, the Y piezoelectric element 55, or both the X piezoelectric element 54 and the Y piezoelectric element 55 displace the sample in a direction of retraction (X direction or Y direction) different from the direction of displacement (Z direction), changing the position of irradiation of the beam on the sample. T_{esc} 162 indicates a retraction time for retracting the sample from the position of irradiation of the beam. Here, the distance of movement on the X-Y plane may be a distance of movement in a case where the X piezoelectric element 54 is used alone, a distance of movement in a case where the Y piezoelectric element 55 is used alone, or a cross product of the amount of movement in a case where both the X piezoelectric element 54 and the Y piezoelectric element 55 are used. Further, the displacement in the direction of retraction may be performed using the X actuator 52 or the Y actuator 53 without using the piezoelectric element.

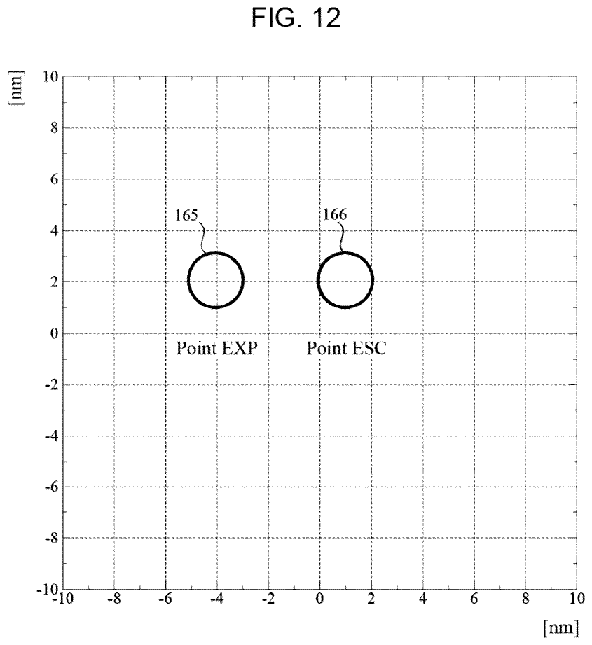

FIG. 12 is a diagram illustrating a relationship between an imaging position and a retraction position of the single Ronchigram, according to Embodiment 3. FIG. 12 is a representation of the X-Y plane on the sample, where the unit of both the vertical and horizontal axes is nm. Point EXP 165 on the X-Y plane is a location for staying in a case of imaging the Ronchigram. Point ESC 166 is a location for staying during the retraction time T_{esc} 162 in FIG. 11.

Point EXP 165 and Point ESC 166 are separate coordinates, and have a characteristic in which the ranges of irradiation of the beam at each of Point EXP 165 and Point ESC 166 do not overlap.

In Embodiment 2, the Z piezoelectric element 65 performs quick movement in the region of the Dₛₑₙₛ 158. However, the imaging location of the Ronchigram on the sample is irradiated with the beam. Therefore, the amorphous thin film is somewhat damaged, leading to deterioration in quality of the Ronchigram. On the other hand, in the present embodiment, the region on the sample irradiated with the beam is changed using the X piezoelectric element 54, the Y piezoelectric element 55, or both the x piezoelectric element 54 and the y piezoelectric element 55 before entry into the region of Dₛₑₙₛ 158 where the amorphous thin film is likely to be damaged. Thereafter, the region on the sample irradiated with the beam is returned to the original position.

With such an operation, it is possible to further reduce damage to the amorphous thin film at the imaging position of the Ronchigram than in Embodiment 2. As a result, it is possible to image the plurality of single Ronchigrams with a high quality.

### <Effects of Embodiment 3>

The region irradiated with the beam is changed using the X piezoelectric element 54, the Y piezoelectric element 55, or both the x piezoelectric element 54 and the y piezoelectric element 55 before entry into the region of Dₛₑₙₛ 158, which is the distance between the focal point and the sample where the amorphous thin film is likely to be damaged. Then, the beam is returned to the imaging position of the Ronchigram after leaving the region. Thereby, it is possible to avoid deterioration in quality of the plurality of single Ronchigrams. With such a configuration, the sixth problem that “in a case of moving across the front focal point and the back focal point, the time during which the sample position stays in the vicinity of the right focal point increases due to the effect of the lens coil time constant, and this damages the amorphous thin film and leads to deterioration in quality of the Ronchigram” is solved. Other effects are the same as the effects in Embodiment 1.

### Embodiment 4

### <Method of Controlling X, Y, and Z Position Detection Elements and X, Y, and Z Piezoelectric Elements in Case of Imaging Ronchigram>

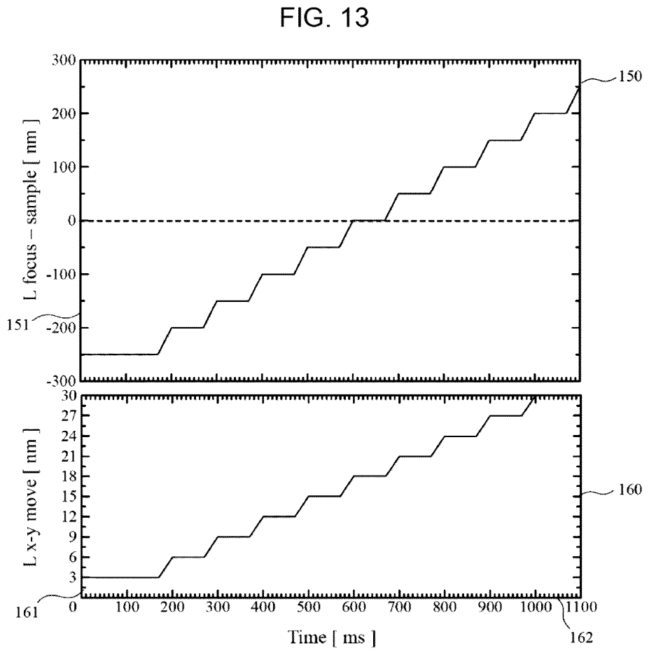

FIG. 13 is a graph illustrating a method of controlling each piezoelectric element having the position detection element in a case of acquiring Ronchigrams, according to Embodiment 4. The meanings of the vertical and horizontal axes and the graph are the same as those of FIG. 11. Thus, the description thereof will not be repeated.

In Embodiment 3, in addition to the time T_{esc} 162 for staying at the retraction position, the time for reaching the retraction position and the time for returning from the retraction position to the imaging position are required, and the time for imaging the plurality of single Ronchigrams increases.

Further, the amorphous thin film is somewhat damaged at any distance between the focal point and the sample. This leads to deterioration in quality of the Ronchigrams as the number of single Ronchigrams to be imaged increases.

Therefore, in the present embodiment, the X piezoelectric element 54 having the X position detection element 70 and the Y piezoelectric element 55 having the Y position detection element 71 displace the sample, in synchronization with the displacement of the sample performed by the Z piezoelectric element 65 having the Z position detection element 72. Then, the Ronchigrams are constantly imaged at different positions of the amorphous thin film.

The graph 160 of the relationship between the time and the distance of movement performed by the X piezoelectric element 54 and the Y piezoelectric element 55 in FIG. 13 shows only the amount of movement of the sample, not the direction of movement. However, the direction of movement of the sample is not limited to one direction. For example, the imaging position of the Ronchigram may be changed by moving the sample in the X direction for the first four times, then moving the sample in the Y direction, and thereafter moving the sample in a direction (−X direction) opposite to the first movement of the X such that the beam scans the sample relatively.

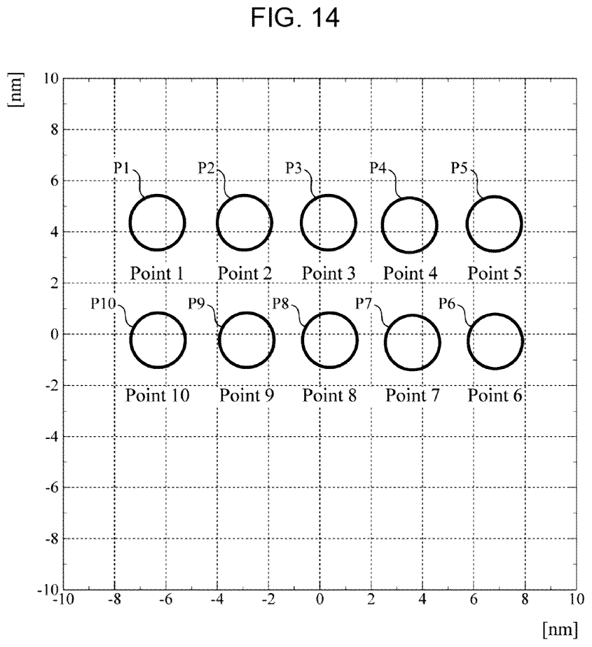

FIG. 14 is a diagram illustrating an imaging position of a plurality of single Ronchigrams, according to Embodiment 4. A first imaging location P1, a second imaging location P2, a third imaging location P3, a fourth imaging location P4, a fifth imaging location P5, a sixth imaging location P6, a seventh imaging location P7, an eighth imaging location P8, a ninth imaging location P9, and a tenth imaging location P10 are separate coordinates from one another, and the beam irradiation ranges at the imaging locations P1 to P10 do not overlap.

In the present embodiment, all the imaging locations are different from one another. However, an example may be assumed in which imaging is performed multiple times, for example, two or three times, at the same location within the number of times that causes a small damage to the amorphous thin film.

The present embodiment is different from Embodiment 3 in that the imaging position of the Ronchigram is different each time. Therefore, the amorphous thin film state which is as uniform as possible and accurate movement in the X-Y plane on the order of several nm are required.

### <Effects of Embodiment 4>

In a case of imaging a plurality of Ronchigrams by using the X piezoelectric element 54 having the X position detection element 70 and the Y piezoelectric element 55 having the Y position detection element 71, it is possible to prevent the quality of the plurality of Ronchigrams from deteriorating by performing imaging while appropriately changing the position of irradiation of the beam on the amorphous thin film. Further, the time required for retraction of the beam and the like, as in Embodiment 3, is not necessary. Therefore, the time required for imaging the plurality of single Ronchigrams can be made equal to the times of Embodiment 1 and Embodiment 2. Thereby, it is possible to obtain the effects of both Embodiment 1 and Embodiment 2.

### Embodiment 5

### <Method of Imaging Ronchigram in Case Where Amorphous Thin Film Is Tilted>

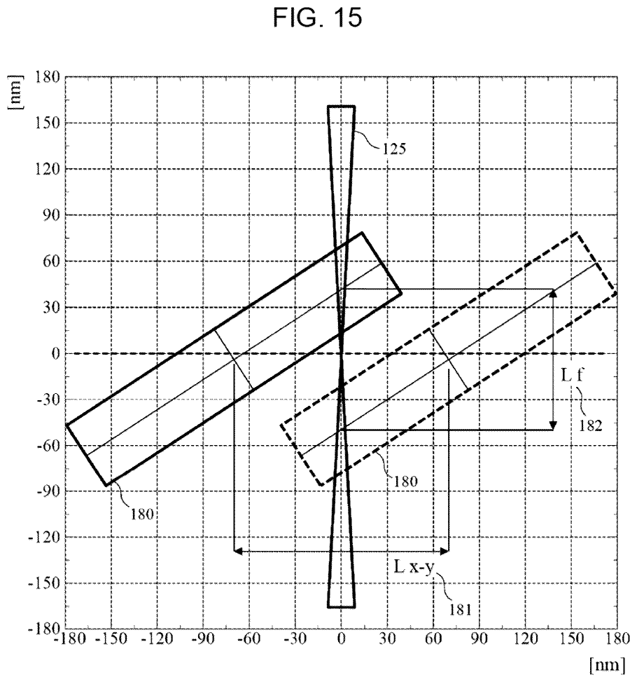

FIG. 15 is a diagram illustrating a positional relationship between a tilted sample and a focal point, according to Embodiment 5. In a case where the amorphous thin film has a tilt or is tilted similarly to the tilted sample 180, for example, in a case where the X piezoelectric element 54 and the Y piezoelectric element 55 move the field of view by L_{x-y} 181, the positional relationship between the sample and the focal point is changed by a distance L_{f} 182. In the example of movement in FIG. 15, movement from the front focal point to the back focal point is possible due to the movement of the X piezoelectric element 54 and the Y piezoelectric element 55. Using the movement, the change in the distance between the focal point and the sample as in FIG. 10 can be realized by movement using the X piezoelectric element 54 and the Y piezoelectric element 55 in the X-Y plane.

### <Effects of Embodiment 5>

The same effects as in Embodiment 4 can be obtained without using the Z piezoelectric element 65 having the Z position detection element 72.

### <Modification Example of Device Configuration>

The device configurations according to Embodiments 1 to 5 are side-entry type device configurations as illustrated in FIGS. 1 to 3. However, the present disclosure is not limited to such configurations.

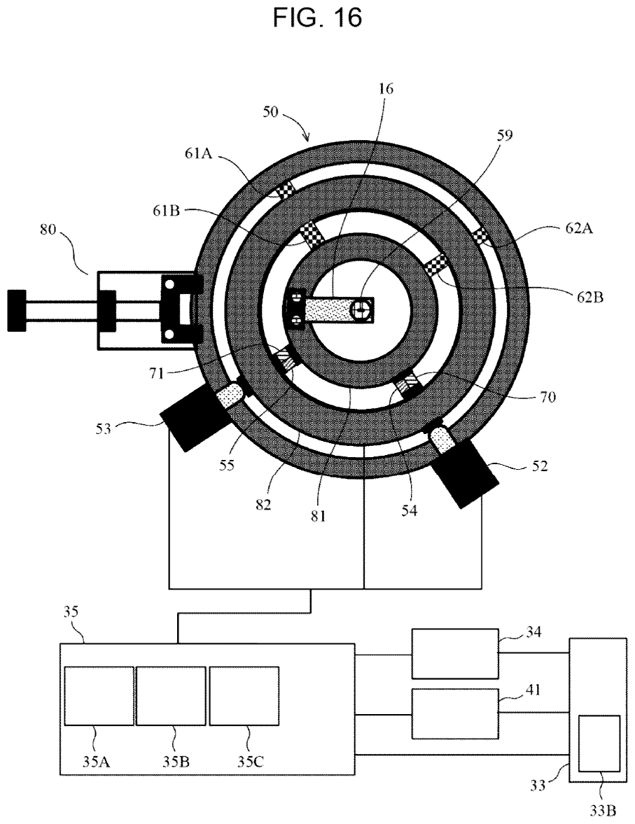

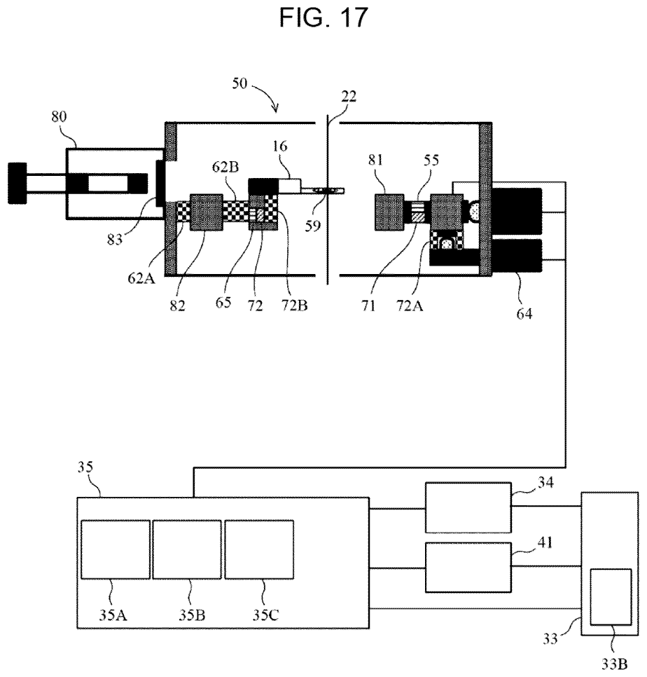

For example, a stage device configuration may be a configuration in which a ring-shaped coarse movement stage is displaced by a coarse movement mechanism disposed concentrically, and a ring-shaped fine movement stage is displaced by a piezoelectric element with a position detection element disposed concentrically. Hereinafter, details of the configuration will be described with reference to FIGS. 16 and 17.

FIG. 16 illustrates a plan view of a stage circumference in the present configuration, and FIG. 17 illustrates a cross-sectional view. It should be noted that parts having the same functions are represented by the same reference numerals and signs as in FIGS. 1, 2, and 3, and a description thereof will not be repeated. The stage in the present configuration is divided into a fine movement stage member 81 and a coarse movement stage member 82, each of which is a ring shape. Further, each of the center of the ring of the fine movement stage member 81 and the center of the ring of the coarse movement stage member 82 is substantially aligned with the optical axis.

It should be noted that the “ring” described in the present disclosure may be substantially the same as a mathematical ring, but it is not necessary for the ring to be completely the same as a mathematical ring. For example, the “ring” according to the present disclosure also includes a ring having a notch in a part of the outer diameter or the inner diameter.

The X and Y directions of the coarse movement stage member 82 are fixed by the X actuator 52, an X coarse movement support 61A, the Y actuator 53, and a Y coarse movement support 62A. A line connecting axes of action of the X actuator 52 and the X coarse movement support 61A and a line connecting axes of action of the Y actuator 53 and the Y coarse movement support 62A are ideally at 90 degrees, and extend in the concentric shape around the optical axis.

The fine movement stage member 81 is fixed by the X piezoelectric element 54 having the X position detection element 70, an X fine movement support 61B, the Y piezoelectric element 55 having the Y position detection element 71, and a Y fine movement support 62B. A line connecting axes of action of the X piezoelectric element 54 having the X position detection element 70 and the X fine movement support 61B and a line connecting axes of action of the Y piezoelectric element 55 having the Y position detection element 71 and the Y fine movement support 62B are ideally at 90 degrees and extend in the concentric shape around the optical axis.

The Z direction of the coarse movement stage member 82 is fixed by the Z actuator 64 and a Z coarse movement support 72A. The Z direction of the fine movement stage member 81 is fixed by the Z piezoelectric element 65 having the Z position detection element 72 and a Z fine movement support 72B.

In a case of replacing the sample, a sample replacement flange 83 is opened, and the sample holder 16 is retrieved using a sample replacement device 80, and is placed on the fine movement stage member 81 by the sample replacement device 80 again after the sample replacement. After the sample replacement operation, the sample replacement flange 83 is closed, and the sample replacement device 80 is separated from the sample holder 16. Due to the characteristic, the sample holder 16 is held in a vacuum and is isolated from atmospheric pressure. In such a manner, as compared with a side-entry type sample holder, image vibration caused by change in atmospheric pressure is reduced, and the effect of drift caused by thermal expansion of the sample holder 16 itself due to change in temperature is reduced.

In the present device configuration as well, it is possible to adopt the method of controlling the piezoelectric element having the position detection element illustrated in FIGS. 4 and 5. Further, the relationship between the position of irradiation of the beam and the distance between the focal point and the sample in a case of acquiring a Ronchigram can be controlled using the piezoelectric element having the position detection element described in Embodiments 1 to 5.

As described above, the present invention has been specifically described on the basis of the above-mentioned embodiments. However, the present invention is not limited to the above-mentioned embodiments and can be modified in various forms without departing from the gist of the present invention.

For example, the above-mentioned embodiments show a case where the transmission charged particle beam device 1 provided with the stage 3 is a scanning/transmission electron microscope (STEM/TEM). However, such a charged particle beam device may be a scanning electron microscope (SEM), a combined device of a scanning ion microscope and a scanning electron microscope (FIB-SEM), or a device to which the microscopes are applied, and may be an device capable of processing, analyzing, and inspecting a sample.

Further, the transmission charged particle beam device 1 according to Embodiment 1 includes not only the Z piezoelectric element 65 but also the X piezoelectric element 54 and the Y piezoelectric element 55 for displacing the sample. However, in Embodiment 1, in a case where the displacement of the sample in the Z direction can be controlled with high accuracy, the X piezoelectric element 54, the Y piezoelectric element 55, and peripheral devices thereof may not be provided.

In Embodiment 5, the positional relationship between the focal point and the sample can be changed without using the Z piezoelectric element 65. Therefore, the Z piezoelectric element 65 and peripheral devices thereof may not be provided.

### REFERENCE SIGNS LIST

1: transmission charged particle beam device
2: control device
3: stage
4: electron gun
5: electron optical system
6: imaging system
7: electron source
8: suppression electrode
9: extraction electrode
10: anode
11: focusing lens
12: deflection lens
13: objective lens
14: stage driving mechanism
15: stage rod
16: sample holder
18: fluorescent screen
19: detector
20: camera
22: primary electrons
23: signal electrons
24: transmitted electrons
25: fluorescence
33: computer
33B: image processing unit
33C: display device
33D: memory
34: main control unit
35: stage control unit
35A: stage operation calculation unit
35B: motor driver
35C: piezoelectric element control unit
36: signal processing unit
40: aberration corrector
41: aberration corrector control unit
50: lens barrel
52: X actuator
53: Y actuator
54: X piezoelectric element
55: Y piezoelectric element
57: X direction
58: Y direction
59, 126, 180: sample
60: stage rod insertion mechanism
61: X support
61A: X coarse movement support
61B: X fine movement support
62: Y support
62A: Y coarse movement support
62B: Y fine movement support
63: Z support
64: Z actuator
65: Z piezoelectric element
66: Z direction
70: X position detection element
71: Y position detection element
72: Z position detection element
72A: Z coarse movement support
72B: Z fine movement support
80: sample replacement device
81: fine movement stage member
82: coarse movement stage member
83: sample replacement flange
102: position detection element signal processor
103: piezoelectric driver
104: comparator
105: digital-to-analog converter
106: analog-to-digital converter
121 to 124: schematic diagram of positional relationship
125: schematic beam trajectory diagram

1. A transmission charged particle beam device that acquires a Ronchigram of a sample and performs aberration correction, comprising:
a piezoelectric element that displaces the sample by expanding and contracting;
a position detection element that detects a position of the sample;
a control unit that controls an amount of expansion or contraction of the piezoelectric element on the basis of the position of the sample detected by the position detection element such that the sample is displaced and the sample is stopped; and
an imaging unit that images one or a plurality of single Ronchigrams without changing a focal position of a beam with which the sample is irradiated in a state where the sample is stopped.

2. The transmission charged particle beam device according to claim 1,
wherein the control unit controls the piezoelectric element such that the piezoelectric element repeatedly displaces and stops the sample, changing stepwise a distance between the position of the sample and the focal position of the beam, and
wherein the imaging unit images the one or the plurality of single Ronchigrams each time the sample is stopped.

3. The transmission charged particle beam device according to claim 1,
wherein, in a case where the sample is displaced to pass through the focal position of the beam, the control unit controls the piezoelectric element such that the piezoelectric element displaces the sample without stopping the sample at least in a range where the focal position of the beam enters the sample.

4. The transmission charged particle beam device according to claim 1,
wherein, in a case where the sample is displaced to pass through the focal position of the beam, the control unit controls the piezoelectric element such that the piezoelectric element displaces the sample at a moving speed faster than a moving speed of the sample before or after the focal position of the beam enters the sample at least in a range where the focal position of the beam enters the sample.

5. The transmission charged particle beam device according to claim 1,
wherein the control unit retracts the sample in a direction of retraction different from a direction of displacement of the sample performed by the piezoelectric element such that the focal position of the beam does not enter the sample.

6. The transmission charged particle beam device according to claim 5,
wherein the control unit retracts the sample in the direction of retraction before the focal position of the beam enters the sample, controls the piezoelectric element such that the piezoelectric element displaces the sample in the direction of displacement, and displaces the sample in a direction opposite to the direction of retraction.

7. The transmission charged particle beam device according to claim 1,
wherein the piezoelectric element is a first piezoelectric element that displaces the sample in a direction of irradiation of the beam,
wherein the transmission charged particle beam device further comprises a second piezoelectric element that displaces the sample in an orthogonal direction which is orthogonal to the direction of irradiation of the beam,
wherein the control unit controls the first piezoelectric element and the second piezoelectric element such that the first piezoelectric element and the second piezoelectric element repeatedly execute displacement of the sample in the direction of irradiation, displacement of the sample in the orthogonal direction, and stopping of the sample, changing a position of irradiation of the beam on the sample and changing stepwise a distance between the position of the sample and the focal position of the beam in the direction of irradiation, and
wherein the imaging unit images the one or the plurality of single Ronchigrams each time the sample is stopped.

8. The transmission charged particle beam device according to claim 7,
wherein the control unit controls the first piezoelectric element and the second piezoelectric element such that the displacement of the sample in the direction of irradiation and the displacement of the sample in the orthogonal direction are synchronized.

9. The transmission charged particle beam device according to claim 1,
wherein the piezoelectric element displaces the sample in a direction orthogonal to a direction of irradiation of the beam, and
wherein the sample is disposed such that a beam irradiation surface of the sample irradiated with the beam is tilted with respect to the direction of irradiation.

10. A Ronchigram imaging method of imaging a Ronchigram of a sample to perform aberration correction, comprising:
controlling an amount of expansion or contraction of a piezoelectric element on the basis of a position of the sample detected by a position detection element, displacing the sample and stopping the sample; and
imaging one or a plurality of single Ronchigrams without changing a focal position of a beam with which the sample is irradiated in a state where the sample is stopped.

11. The Ronchigram imaging method according to claim 10,
wherein the displacing of the sample includes
controlling the piezoelectric element such that the piezoelectric element repeatedly displaces and stops the sample, changing stepwise a distance between the position of the sample and the focal position of the beam, and
wherein the imaging of the single Ronchigram includes
imaging the one or the plurality of single Ronchigrams each time the sample is stopped.

12. The Ronchigram imaging method according to claim 10,
wherein the displacing of the sample includes
displacing the sample without stopping the sample at least in a range where the focal position of the beam enters the sample by controlling the piezoelectric element, in a case where the sample is displaced to pass through the focal position of the beam.

13. The Ronchigram imaging method according to claim 10,
wherein the displacing of the sample includes
displacing the sample at a moving speed faster than a moving speed of the sample before or after the focal position of the beam enters the sample at least in a range in which the focal position of the beam enters the sample by controlling the piezoelectric element, in a case where the sample is displaced to pass through the focal position of the beam.

14. The Ronchigram imaging method according to claim 10, further comprising
retracting the sample in a direction of retraction different from a direction of displacement of the sample performed by the piezoelectric element such that the focal position of the beam does not enter the sample.

15. The Ronchigram imaging method according to claim 14,
wherein the retracting of the sample includes
retracting the sample in the direction of retraction before the focal position of the beam enters the sample,
controlling the piezoelectric element so as to displace the sample in the direction of displacement, and
displacing the sample in a direction opposite to the direction of retraction.

16. The Ronchigram imaging method according to claim 10,
wherein the displacing of the sample includes
controlling a first piezoelectric element that displaces the sample in a direction of irradiation of the beam and a second piezoelectric element that displaces the sample in an orthogonal direction orthogonal to the direction of irradiation of the beam such that the first piezoelectric element and the second piezoelectric element repeatedly execute displacement of the sample in the direction of irradiation, displacement of the sample in the orthogonal direction, and stopping of the sample, changing a position of irradiation of the beam on the sample and changing stepwise a distance between the position of the sample and the focal position of the beam in the direction of irradiation, and
wherein the imaging of the single Ronchigram includes
imaging the one or the plurality of single Ronchigrams each time the sample is stopped.

17. The Ronchigram imaging method according to claim 16,
wherein the controlling of the first piezoelectric element and the second piezoelectric element includes
controlling the first piezoelectric element and the second piezoelectric element such that the displacement of the sample in the direction of irradiation and the displacement of the sample in the orthogonal direction are synchronized.

18. The Ronchigram imaging method according to claim 10, further comprising:
disposing the sample such that a beam irradiation surface of the sample irradiated with the beam is tilted with respect to a direction of irradiation of the beam,
wherein the displacing of the sample includes
controlling the piezoelectric element such that the piezoelectric element displaces the sample in a direction orthogonal to the direction of irradiation of the beam.
